(19) United States
(12) Patent Application Publication
(10) Pub. No.: US 2025/0233083 A1
(43) Pub. Date: Jul. 17, 2025

(54) ELECTRONIC DEVICES AND METHODS OF MANUFACTURING ELECTRONIC DEVICES

(71) Applicant: Amkor Technology Singapore Holding Pte. Ltd., Valley Point #12-03 (SG)

(72) Inventors: Young Do KWEON, Chandler, AZ (US); Dong Hyeon PARK, Seoul (KR); Yu Jin JEON, Incheon (KR); Ji Young JEONG, Gyeonggi-do (KR); Young Jun KOO, Incheon (KR); Dong Su RYU, Incheon (KR)

(73) Assignee: Amkor Technology Singapore Holding Pte. Ltd., Valley Point #12-03 (SG)

(21) Appl. No.: 18/411,911

(22) Filed: Jan. 12, 2024

(51) Int. Cl. H01L 23/00; H01L 23/31; H01L 23/367; H01L 25/00; H01L 25/065; H01L 25/16

(52) U.S. Cl. CPC H01L 23/562; H01L 23/3128; H01L 23/367; H01L 24/29; H01L 24/32; H01L 25/0655; H01L 25/16; H01L 25/50; H01L 24/13; H01L 24/16; H01L 24/30; H01L 24/33; H01L 24/73; H01L 2224/13111; H01L 2224/13116; H01L 2224/13124; H01L 2224/13139; H01L 2224/13144; H01L 2224/13147; H01L 2224/13155; H01L 2224/13164; H01L 2224/13166; H01L 2224/13184; H01L 2224/16227; H01L 2224/29006; H01L 2224/29105; H01L 2224/29109; H01L 2224/29111; H01L 2224/29118; H01L 2224/29139; H01L 2224/2919; H01L 2224/30505; H01L 2224/32225; H01L 2224/32245; H01L 2224/33181; H01L 2224/73204; H01L 2224/73253; H01L 2924/0132; H01L 2924/0665; H01L 2924/069; H01L 2924/07025

(57) ABSTRACT

An electronic device includes a substrate including a first side comprising a peripheral portion and a central portion surrounded by the peripheral portion, and a conductive structure. A first electronic component includes a component first side coupled to the substrate in the central portion and a component second side. A second electronic component is coupled to the substrate in the peripheral portion. An encapsulant covers the second electronic component and the peripheral portion of the first side. The second side of the first electronic component is exposed from the top side of the encapsulant. A thermal stress reducing structure comprising one or more of a stiffener coupled to the top side of the encapsulant in the peripheral portion and overlapping the second electronic component, or a heat sink coupled to the second side of the first electronic component. Other examples and related methods are also disclosed herein.

### TECHNICAL FIELD

The present disclosure relates, in general, to electronic devices, and more particularly, to semiconductor devices and methods for manufacturing semiconductor devices.

### BACKGROUND

Prior semiconductor packages and methods for forming semiconductor packages are inadequate, for example resulting in excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A, 2B, 20, 2D, 2E, 2F, 2G, and 2H show cross-sectional views of an example method for manufacturing an example electronic device.

FIG. 3 shows a cross-sectional view of an example electronic device.

FIGS. 4A, 4B, 4C, 4D, 4E, and 4F show cross-sectional views of an example method for manufacturing an example electronic device.

FIG. 5 shows a cross-sectional view of an example electronic device.

FIGS. 6A, 6B, 6C, and 6D show cross-sectional views of an example method for manufacturing an example electronic device.

FIG. 7 shows a cross-sectional view of an example electronic device.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of the stated features, but do not preclude the presence or addition of one or more other features.

The terms “first,” “second,” etc. may be used herein to describe various elements, and the elements described using “first,” “second,” etc. should not be limited by the terms “first,” “second,” etc. The terms “first,” “second,” etc. are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly connected by one or more other elements. For example, if element A is coupled to element B, then element A can be directly contacting element B or indirectly connected to element B by an intervening element C. Similarly, the terms “over” or “on” may be used to describe two elements directly contacting each other or describe two elements indirectly connected by one or more other elements. As used herein, the term “coupled” can refer to an electrical coupling or a mechanical coupling.

### DESCRIPTION

The present description includes, among other features, structures and associated methods that relate to packaged electronic devices that are more resilient to thermal stress. More particularly, structures and methods are described that improve the reliability of packaged electronic devices that reduce defects associated with thermal stress, such warpage, package distortion, bending, component cracking, or delamination. In some examples, a thermal stress reducing structure comprising an extended stiffener overlying an encapsulant is used to reduce warpage of thin packaging substrates, such as thin core or coreless substrates. In some examples, the thermal stress reducing structure comprises a heat sink coupled to the extended stiffener. In some examples, a liquid thermal interface material (TIM) is used together with the extended stiffener or the heat sink. In some examples, electronic components are exposed from a top side of the encapsulant and can include a metallization layer that improves heat transfer performance and improves adhesion with the liquid TIM. In some examples, the encapsulant covers electronic components at the periphery of the package substrate to provide extended support for the extended stiffener.

In an example, an electronic device includes a substrate including a first side comprising a peripheral portion and a central portion surrounded by the peripheral portion, a second side opposite to the first side, a dielectric structure, and a conductive structure. A first electronic component includes a component first side coupled to the conductive structure at the first side of the substrate in the central portion, a component second side opposite to the component first side, and a component lateral side connecting the component first side to the component second side. A second electronic component is coupled to the first side of the substrate in the peripheral portion. An encapsulant covers the second electronic component and the peripheral portion of the first side of the substrate. The second side of the first electronic component is exposed from a top side of the encapsulant. A stiffener is coupled to the top side of the encapsulant in the peripheral portion and overlaps the second electronic component.

In an example, an electronic device includes a substrate including a first side comprising a peripheral portion and a central portion surrounded by the peripheral portion, a second side opposite to the first side, a dielectric structure, and a conductive structure. A first electronic component includes a component first side coupled to the conductive structure at the first side of the substrate in the central portion, a component second side opposite to the component first side, and a component lateral side connecting the component first side to the component second side. A second electronic component is coupled to the first side of the substrate in the peripheral portion. An encapsulant covers the second electronic component and the peripheral portion of the first side. The second side of the first electronic component is exposed from a top side of the encapsulant. A thermal stress reducing structure comprising one or more of a stiffener coupled to the top side of the encapsulant in the peripheral portion and overlapping the second electronic component, or a heat sink coupled to the second side of the first electronic component.

In an example, a method of manufacturing an electronic device includes providing a substrate including a first side comprising a peripheral portion and a central portion surrounded by the peripheral portion, a second side opposite to the first side, a dielectric structure, and a conductive structure. The method includes providing a first electronic component including a component first side coupled to the conductive structure at the first side of the substrate in the central portion, a component second side opposite to the component first side, and a component lateral side connecting the component first side to the component second side. The method includes providing a second electronic component coupled to the first side of the substrate in the peripheral portion. The method includes providing an encapsulant covering the second electronic component and the peripheral portion of the first side, wherein the second side of the first electronic component is exposed from a top side of the encapsulant. The method includes providing a thermal stress reducing structure comprising one or more of a stiffener coupled to the top side of the encapsulant in the peripheral portion and overlapping the second electronic component, or a heat sink coupled to the second side of the first electronic component.

Other examples are included in the present disclosure. Such examples may be found in the figures, in the claims, and/or in the description of the present disclosure.

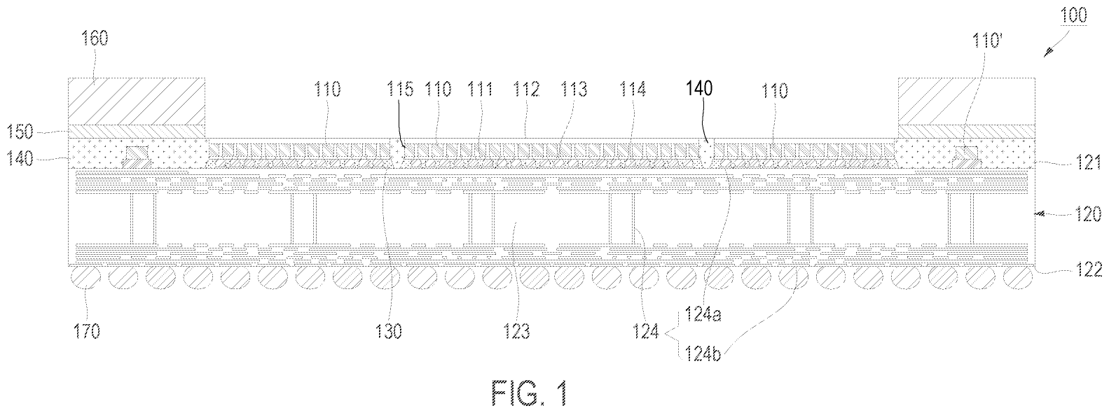

FIG. 1 shows a cross-sectional view of an example electronic device 100. In the example shown in FIG. 1, electronic device 100 can comprise electronic components 110, electronic components 110′, substrate 120, interface material 130, encapsulant 140, adhesive 150, stiffener 160, and external interconnects 170. Stiffener 160 is an example of a thermal stress reducing structure.

Electronic components 110 can each a comprise a first side 111, a second side 112 opposite to first side 111, and a lateral side 115 connecting first side 111 to second side 112. In some examples, first sides 111 of electronic components 110 can comprise or be referred to as active sides where circuit elements can be formed, and second sides 112 of electronic components 110 can comprise or be referred to as inactive sides. First side 111 can also be referred to as or comprise a component first side and second side 112 can also be referred to or comprises a component second side. In some examples, electronic components 110 can comprise contact pads 113 proximate to first sides 111, which can be coupled to the circuit elements and devices formed as part of electronic components 110.

Substrate 120 can comprise a first side 121 and a second side 122. First side 121 of substrate 120 can also be referred to as a substrate first side, substrate top side, or a substrate inner side, and second side 122 of substrate 120 can be referred to as a substrate second side, substrate bottom side, or a substrate outer side. In the present example, first sides 111 of electronic components 110 are proximate to first side 121 of substrate 120 and second sides 112 of electronic components 110 are distal to first side 121 of substrate 120.

In some examples, substrate 120 can comprise a dielectric structure 123 and a conductive structure 124. Conductive structure 124 can comprise substrate inward terminals 124a and substrate outward terminals 124b. In some examples, electronic device 100 comprises component interconnects 114, which couple contact pads 113 to inward terminals 124a. Component interconnects 114 can also be referred to as connectors or interconnects. In the present example, electronic components 110 are coupled to substrate 120 in a flip-chip configuration or active side down configuration. Interface material 130 can be interposed between electronic components 110 and substrate 120 and can laterally surround component interconnects 114. In some examples, interface material 130 can be along lateral sides 115 of electronic components 110. Interface material 130 can be configured to protect component interconnects 114 and to improve the adhesion of electronic components 110 to substrate 120. Interface material 130 can also be referred to as or comprise an underfill.

In the present example, encapsulant 140 is provided at peripheral portions of top side 121 of substrate 120 surrounding electronic components 110 and covering electronic components 110′. In some examples, second sides 112 of electronic components 110 can be substantially coplanar and exposed from a top side of encapsulant 140. In some examples, encapsulant 140 is laterally extended to cover electronic components 110′ and can be provided adjoining lateral sides 115 of electronic components 110. In some examples, stiffener 160 is coupled to a top side of encapsulant 140 proximate to the peripheral portions of top side 121 of substrate 120. In some examples, stiffener 160 is attached to the top side of encapsulant 140 with adhesive 150 and is laterally extended to overlie electronic components 110′. Stiffener 160 is configured to reduce warpage of electronic device 100. Stiffener 160 is an example of a thermal stress reducing structure. In some examples, encapsulant 140 and stiffener 160 laterally extend and terminate proximate to lateral side 115 of the outermost ones of electronic components 110.

Substrate 120, interface material 130, encapsulant 140, adhesive 150, stiffener 160, and external interconnects 170 can be referred to as an electronic package or package. The electronic package can protect electronic components 110 and 110′ from exposure to external elements and/or environments. The electronic package can also provide electrical coupling between electronic components 110, between electronic component(s) 110 and electronic component(s) 110′, or between electronic component(s) 110 and an external component or other electronic packages.

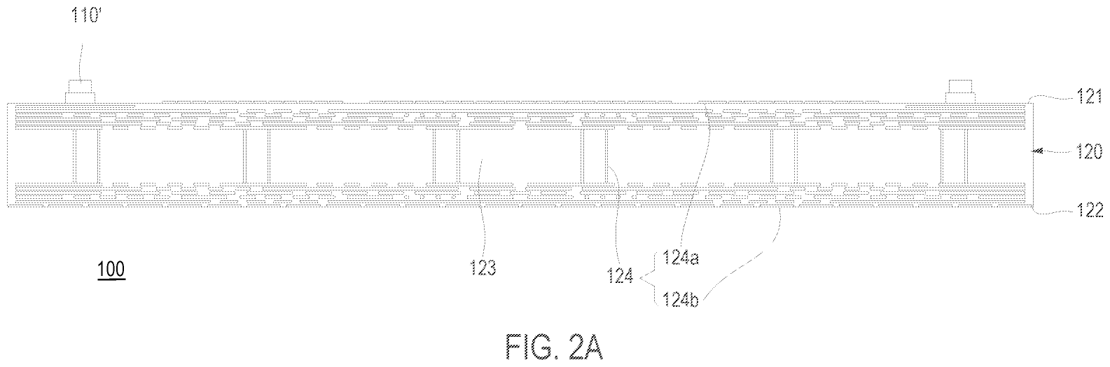

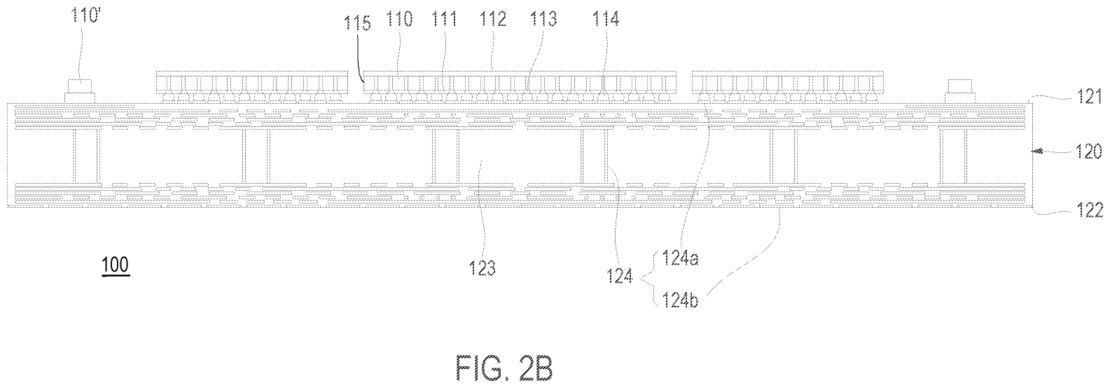

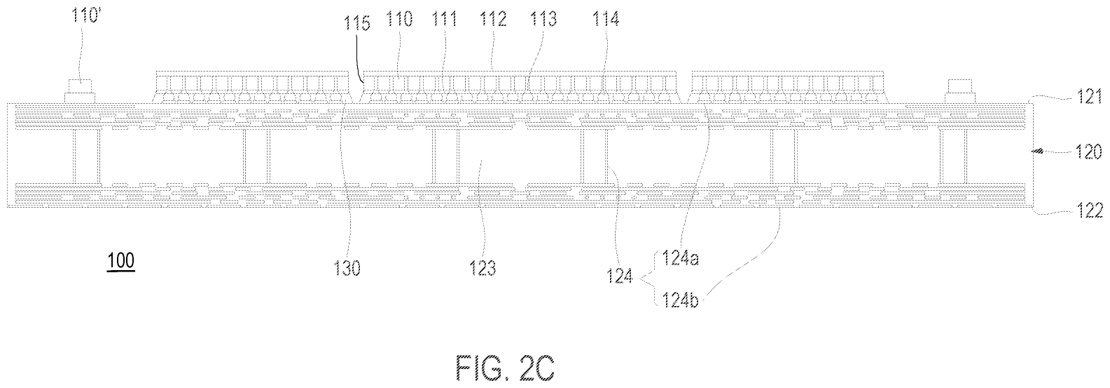

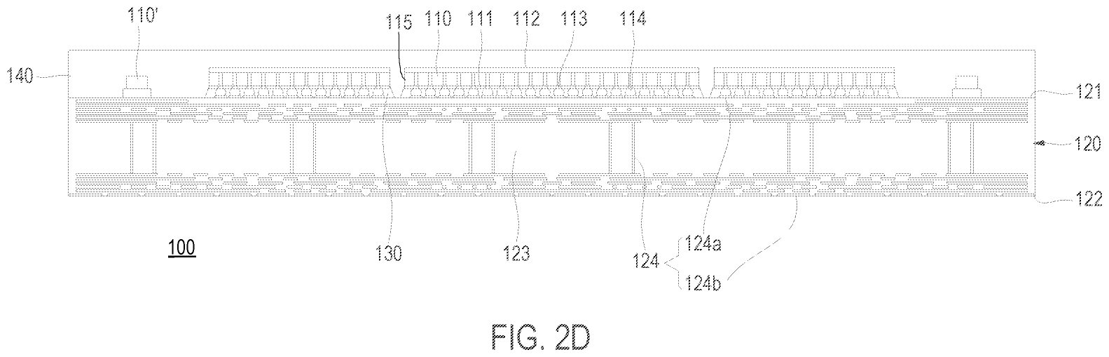

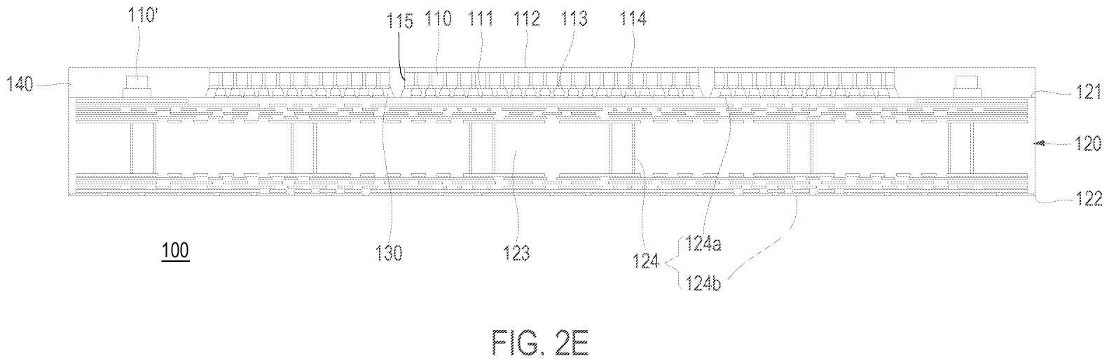

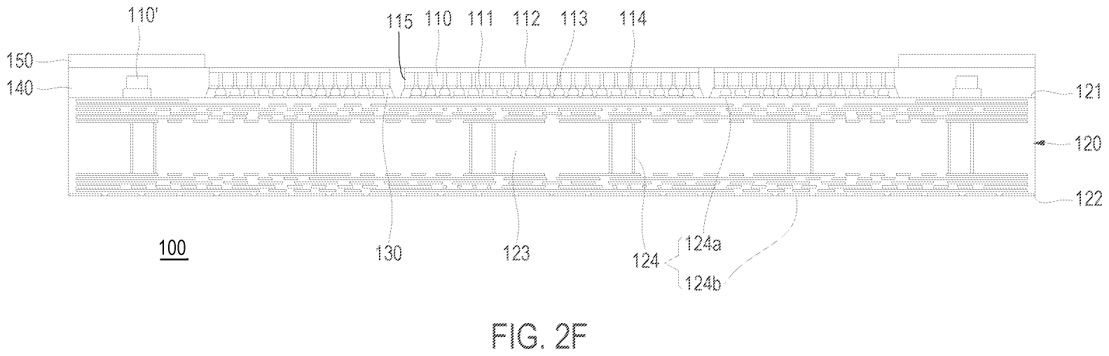

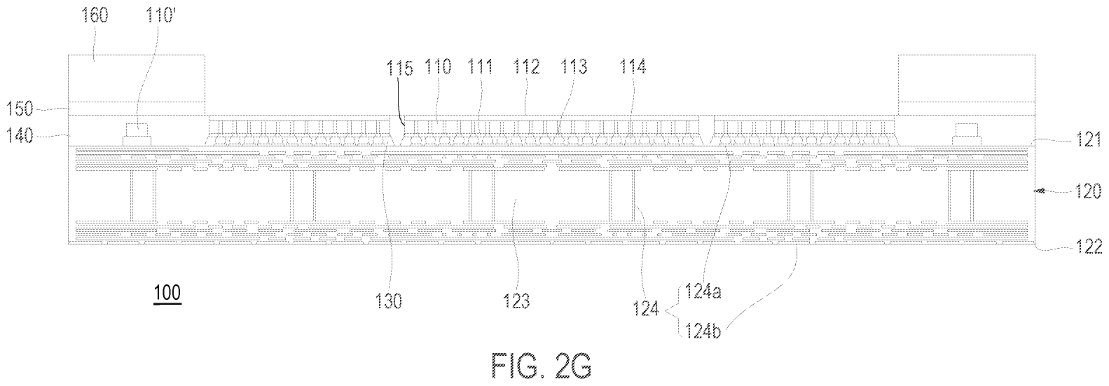

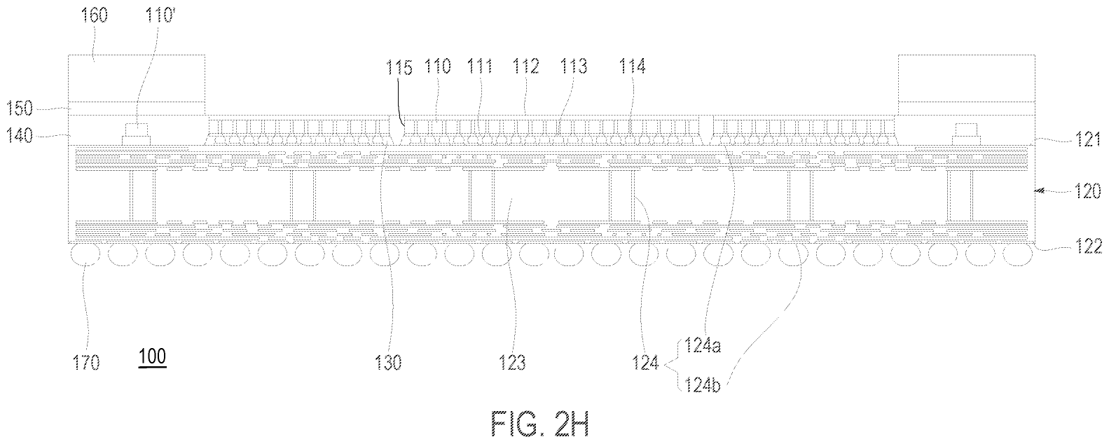

FIGS. 2A, 2B, 2C, 2D, 2E, 2F, 2G, and 2H show cross-sectional views of an example method for manufacturing an electronic device, such as electronic device 100.

FIG. 2A shows electronic device 100 at an early stage of manufacture. In the example shown in FIG. 2A, substrate 120 can be provided and electronic components 110′ can be provided on first side 121 of substrate 120. In some examples, substrate 120 can comprise a thin core (e.g., a core thickness of less than 1.24 mm). For example, substrate 120 can comprise a core thickness in a range of approximately 0.5 mm to approximately 1.20 mm, approximately 0.5 mm to approximately 1.00 mm, or of approximately 0.8 mm. In some examples, substrate 120 can be coreless. For example, the thickness of substrate 120 can be in a range of approximately 40 μm (micrometers) to approximately 3500 μm, approximately 100 μm to approximately 1500 μm, or 800 μm to approximately 1000 μm. In some examples, substrate 120 can comprise or be referred to as a laminate substrate, a redistribution layer (RDL) substrate, a buildup substrate, a coreless substrate, a rigid substrate, a glass substrate, a semiconductor substrate, a printed circuit board, a multi-layer substrate, a molded lead frame, a ceramic substrate, a glass substrate, a silicon substrate, or a package substrate. In some examples, substrate can have an area (or “footprint”) in the range of approximately 5 mm×5 mm to approximately 110 mm×110 mm.

In some examples, substrate first side 121 can be configured for mounting electronic components 110 and 110′. In some examples, substrate second side 122 can be configured for mounting external interconnects 170 (FIG. 1) or additional electronic components.

In some examples, conductive structure 124 can comprise or be referred to as one or more conductors, conductive materials, conductive paths, conductive layers, RDLs, wiring layers, signal distribution elements, traces, vias, pads, or under bump metallization (UBM). In some examples, one or more of the conductive layers can be interleaved with dielectric layers of dielectric structure 123. In some examples, conductive structure 124 can comprise copper (Cu), aluminum (Al), nickel (Ni), palladium (Pd), titanium (Ti), tungsten (W), titanium/tungsten, gold (Au), silver (Ag), an alloy, or other suitably conductive material as known to one of ordinary skill in the art. In some examples, conductive structure 124 can be provided by sputtering, electroless plating, electrolytic plating, physical vapor deposition (PVD), chemical vapor deposition (CVD), metal organic chemical vapor deposition (MOCVD), atomic layer deposition (ALD), low pressure chemical vapor deposition (LPCVD), plasma enhanced chemical vapor deposition (PECVD), or other processes as known to one of ordinary skill in the art. In some examples, portions of conductive structure 124 can be exposed from first side 121 of substrate 120 and from second side 122 of substrate 120.

In some examples, conductive structure 124 can comprise substrate inward terminals, inner contact pads, traces, or lands 124a and substrate outward terminals, outer contact pads, traces, or lands 124b. In some examples, substrate inward terminals 124a can be exposed from first side 121 of substrate 120 and substrate outward terminals 124b can be exposed from second side 122 of substrate 120. In some examples, substrate inward terminals 124a or substrate outward terminals 124b can be provided in a matrix form having rows or columns. Conductive structure 124 can be coupled to electronic components 110 and 110′ (for example, using substrate inward terminals 124a) and external interconnects 170 (for example, using substrate outward terminals 124b) (FIG. 1). Conductive structure 124 can transmit signals, currents, or voltages within substrate 120. In some examples, the thickness of conductive structure 124 can range from about 1 μm to about 50 μm. The thickness of conductive structure 124 can refer to individual layers (for example, substrate inward terminals 124a or substrate outward terminal 124b) of conductive structure 124. Conductive structure 124 can provide an electrical signal path (e.g., a vertical path or a horizontal path) between electronic components.

In some examples, dielectric structure 123 can comprise or be referred to as one or more dielectrics, dielectric materials, dielectric layers, passivation layers, insulating layers, or protective layers. In some examples, dielectric structure 123 can have a structure where one or more dielectric layers are stacked or interleaved with layers of conductive structure 124. In some examples, dielectric structure 123 can comprise FR4 (copper foil/glass fiber fabric/copper foil laminate), bismaleimide triazine (BT), polymer, polyimide (PI), benzocyclobutene (BCB), polybenzoxazole (PBO), Ajinomoto Build-up Film (ABF), resin, a molding material, phenolic resin, epoxy, silicone, acrylate polymer ceramic, glass, or silicon.

Dielectric structure 123 can maintain the outer shape of substrate 120 and can also structurally support conductive structure 124 and electronic components 110 and 110′. In some examples, dielectric structure 123 can be in contact with conductive structure 124. Dielectric structure 123 can expose portions of conductive structure 124. For example, substrate inward terminals 124a can be exposed from an upper side of dielectric structure 123 and substrate outward terminals 124b can be exposed from a lower side of dielectric structure 123. In some examples, dielectric structure 123 can be provided by spin coating, spray coating, printing, oxidation, PVD, CVD, MOCVD, ALD, LPCVD, PECVD, or other processes as known to one of ordinary skill in the art.

The upper and lower sides of dielectric structure 123 can be part of first side 121 of substrate 120 and second side 122 of substrate 120, respectively. In some examples, the thicknesses of individual layers of dielectric structure 123 can range from about 3 μm to about 100 μm. The combined thickness of all layers of dielectric structure 123 can define the thickness of substrate 120. In some examples, the total thickness of dielectric structure 123 can range from about 10 μm to 2500 μm. The individual layers of dielectric structure 123 can have different thicknesses and can comprise different materials.

Electronic components 110 or 110′ or other components or packages can be coupled to substrate inward terminals 124a in a subsequent process. In some examples, electronic components 110′ can be initially coupled to substrate inward terminals 124a. In other examples, electronic components 110′ can be coupled to substrate 120 during a subsequent coupling process of electronic components 110, or electronic components 110′ can be coupled after the coupling process of electronic components 110. In some examples, multiple electronic components 110′ can be arrayed around top side 121 of substrate 120. In accordance with the present description, the area of top side 121 is pre-determined to accommodate electronic components 110 in a central portion of top side 121 and to accommodate stiffener 160 at the peripheral portions of top side 121 overlying electronic components 110′. In some examples, electronic components 110′ can comprise or be referred to as a passive component, an antenna patch, an integrated passive device (IPD), or an active device. Electronic components 110′ can be mounted to top side 121 in chip form or in packaged form. Substrate 120 can couple electronic components 110 and 110′ to each other and can protect the electronic components from external stress.

Substrate 120 can be manufactured using various processing techniques. For example, when substrate 120 comprises a two-layer FR4 substrate, substrate 120 can be manufactured by the steps of: processing a drill hole to couple a top copper foil and a bottom copper foil; coupling the top copper foil and the bottom copper foil by performing electroplating on the drill hole; providing a photosensitive film on the side of the substrate and photo-etching the photosensitive film so the sides of the top copper foil and the bottom copper foil are patterned, thereby patterning an outer-layer circuit including substrate inward terminals 124a and substrate outward terminals 124b on the top side 121 and bottom side 122 of the substrate 120; providing a seed layer for plating, which can be thinner than the outer-layer circuit, by performing electroless plating on the entire top side and bottom side of the substrate to cover the outer-layer circuit; providing a photosensitive film on the seed layer for plating so as to cover the seed layer for plating, and performing photo-etching on the photosensitive film to pattern the seed layer for plating; providing a solder resist layer on the entire top side and bottom side of the substrate so the outer-layer circuit is exposed; and forming a plating layer on the outer-layer circuit including substrate inward terminals 124a and substrate outward terminals 124b exposed from the solder resist layer by applying electricity to the plating seed layer.

In an example where substrate 120 comprises a three to six-layer substrate having more than two layers, an inner-layer circuit providing step and a laminating step are added in the manufacture of substrate 120. As an example, the inner-layer circuit providing step can be performed by patterning an inner layer circuit on the top side and bottom side of each substrate by photo-etching a photosensitive film so the sides of a top copper foil and a bottom copper foil are patterned for each substrate. As an example, the lamination step can be performed by aligning each of the provided substrates and allowing each of the substrates to be integrated into one substrate while providing a predetermined temperature and pressure. In some examples, the dielectric structure can be a B-stage prepreg, and since the dielectric structure is in a C-stage state after the lamination step, each substrate can be integrated to provide one multilayer substrate. In some examples, after the lamination process, a hole processing step, a plating step, or an outer-layer circuit providing step can be sequentially provided in similar manner as described above.

In some examples, substrate 120 can be a pre-formed substrate. Pre-formed substrates can be manufactured prior to attachment to an electronic device and can comprise dielectric layers between respective conductive layers. The conductive layers can comprise copper and can be formed using an electroplating process. The dielectric layers can be relatively thicker (for example, thicker than the conductive layers) non-photo-definable layers and can be attached as a pre-formed film rather than as a liquid and can include a resin with fillers such as strands, weaves, and/or other inorganic particles for rigidity and/or structural support. Since the dielectric layers are non-photo-definable, features such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a dielectric material comprising bismaleimide triazine (BT) or FR4, and dielectric and conductive layers can be formed on the permanent core structure. In other examples, the pre-formed substrate can be a coreless substrate and omits the permanent core structure, and the dielectric and conductive layers can be formed on a sacrificial carrier and is removed after formation of the dielectric and conductive layers and before attachment to the electronic device. The pre-formed substrate can be referred to as a printed circuit board (PCB) or a laminate substrate. Such pre-formed substrate can be formed through a semi-additive process or a modified-semi-additive process.

In other examples, substrate 120 can be an RDL substrate. RDL substrates can comprise one or more conductive redistribution layers and one or more dielectric layers and (a) can be formed layer by layer over an electronic component to where the RDL substrate is to be coupled, or (b) can be formed layer by layer over a temporary carrier that can be entirely removed or at least partially removed after the electronic component and the RDL substrate are coupled together. RDL substrates can be manufactured layer by layer as a wafer-level substrate on a round wafer in a wafer-level process, and/or as a panel-level substrate on a rectangular or square panel carrier in a panel-level process. RDL substrates can be formed in an additive buildup process and can include one or more dielectric layers alternatingly stacked with one or more conductive layers and define respective conductive redistribution patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise a conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process and can include a photolithographic mask through where light is exposed to photo-pattern desired features such as vias in the dielectric layers. The dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of inorganic dielectric layer(s) can comprise silicon nitride (Si₃N₄), silicon oxide (SiO₂), or silicon oxynitride (SiON). The inorganic dielectric layer(s) can be formed by growing the inorganic dielectric layers using an oxidation or nitridization process instead using photo-defined organic dielectric materials. Such inorganic dielectric layers can be filler-free, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can comprise or be referred to as a coreless substrate.

FIG. 2B shows a cross-sectional view of electronic device 100 at a later stage of manufacture. In the example shown in FIG. 2B, one or more electronic components, such as electronic components 110, can be coupled to top side 121 of substrate 120. In the present example, multiple electronic components 110 will be described, but it is understood a single electronic component 110 can be used.

In some examples, electronic components 110 can be located at a central portion or region of first side 121 of substrate 120. In some examples, electronic components 110 can comprise or be referred to as dies, chips, or packages. In some examples, one or more of electronic components 110 can comprise a memory, a digital signal processor (DSP), a microprocessor, a network processor, a power management processor, an audio processor, an RF circuit or module, a mmWave module, an antenna structure, a wireless baseband system-on-chip (SoC) processor, a power semiconductor device, a sensor, or an application specific integrated circuit (ASIC).

Electronic components 110 can each comprise first side 111 configured as an active side, second side 112 configured as an inactive side, and lateral side 115 connecting first side 111 to second side 112. First sides 111 and second sides 112 face opposite directions. In some examples, first sides 111 can face substrate first side 121 of substrate 120. Electronic components 110 can each comprise contact pads 113. Contact pads 113 of electronic components 110 can be provided on respective first sides 111 of electronic components 110. Contact pads 113 can be input/output terminals for electronic components 110. In some examples, contact pads 113 of electronic components 110 can be provided to be spaced apart from each other in a row or column direction on respective first sides 111 of electronic component 110. In some examples, contact pads 113 of electronic components 110 can be bond pads, or RDL pads exposed through a dielectric material provided as part of electronic components 110. In some examples, the dielectric material can comprise a nitride or an oxide. Electronic component 110 can be coupled to substrate 120 with component interconnects 114 in contact with or electrically connected to contact pads 113 of electronic components 110 and substrate inward terminals 124a of conductive structure 124.

In some examples, component interconnects 114 can comprise or be referred to as bumps, tin/lead (SnPb) bumps, leadfree bumps, CuP, stud bumps, pillars, posts, solder capped pillars, or solder coated copper core balls. In some examples, component interconnects 114 can be provided over contact pads 113 of electronic component 110. In some examples, component interconnects 114 can comprise Cu, Pb, Sn, Al, Pd, Ti, W, Ti/W, Ni, Au, or Ag. In some examples, component interconnects 114 can have a thickness (height) of approximately 10 μm to approximately 300 μm and a pitch of approximately 10 μm to approximately 300 μm.

In some examples, pick-and-place equipment can pick up electronic components 110 and place electronic components 110 on first side 121 of substrate 120. Interconnects 114 can be positioned on substrate inward terminals 124a of substrate 120. Subsequently, component interconnects 114 of electronic components 110 can be in contact with and be bonded to substrate inward terminals 124a of substrate 120 through a mass reflow process, a thermal compression process, a laser bonding process, or other bonding processes as known to one of ordinary skill the art. In some examples, the overall thickness of electronic components 110 can range from about 40 μm to about 1000 μm, and the area (or “footprint”) of each electronic component 110 can range from about 1.0 mm×1.0 mm to about 70 mm×70 mm. In some examples, electronic components 110 or other electronic components can be provided on second side 122 of substrate 120. In some examples, second sides 112 of electronic components can be provided with a metallization layer prior to being located over substrate 120.

In some examples, larger ones of electronic components 110 (for example, larger lateral width or larger thickness relative to other ones of electronic components 110) can be attached to an approximately central region of substrate 120, and electronic components 110′ can be attached proximate to the peripheral region of substrate 120. Smaller ones of electronic components 110 (for example, smaller lateral widths or smaller thicknesses relative to other ones of electronic components 110) can be attached to substrate 120 between the larger ones of electronic components 110 and electronic components 110′. Electronic components 110 can perform various calculations and control processing, store data, remove noise from an electrical signal, transmit/receive radio frequencies, or other functionality.

FIG. 2C shows a cross-sectional view of electronic device 100 at a later stage of manufacture. In the example shown in FIG. 2C, interface material 130 can be provided between substrate 120 and electronic components 110. Interface material 130 can be referred to as or comprise a capillary underfill, a no-flow underfill (also called a non-conductive paste (NCP)), a wafer level underfill (also called a B-stage underfill), a molded underfill (MUF), a non-conductive film (NCF), or an anisotropic conductive film (ACF). In some examples, interface material 130 can comprise epoxy, a thermoplastic material, a thermosetting material, polyimide, polyurethane, a polymeric material, filled epoxy, a filled thermoplastic material, a filled thermosetting material, filled polyimide, filled polyurethane, a filled polymeric material, or a fluxing underfill.

In some examples, after electronic components 110 are coupled to substrate 120, interface material 130 can be injected into a gap between electronic components 110 and substrate 120 (e.g., capillary underfill). In some examples, after interface material 130 is applied onto substrate 120, electronic components 110 can be pressed into interface material 130 (e.g., no-flow underfill). In some examples, after interface material 130 is applied onto connectors 114 of electronic components 110, electronic components 110 can be attached to substrate 120 while pressing interface material 130 (e.g., wafer level underfill). In some examples, interface material 130 can fill the gap between electronic components 110 and substrate 120 and can wrap electronic component 110. In some examples, interface material 130 can be positioned on substrate inward terminal 124a of substrate 120 in the form of a film, and after electronic components 110 are pressed, an underfill curing process can be performed (e.g., a non-conductive film (NCF)). In this way, interface material 130 can be positioned between electronic component 110 and substrate 120 to cover or surround connectors 114 so that electronic components 110 and substrate 120 can be coupled to each other. Interface material 130 contacts first side 121 of substrate 120 and first sides 111 of electronic components 110. In other examples, interface material 130 can cover, at least, a lower portion of lateral sides 115 of electronic components 110. In some examples, interface material 130 can be cured after being interposed between electronic components 110 and substrate 120.

Interface material 130 can redistribute stress and strain due to a difference in the coefficient of thermal expansion between electronic components 110 (e.g., CTE: 2-4 ppm/° C.) and substrate 120 (e.g., CTE: 20-30 ppm/° C.), can prevent moisture penetration, can prevent a physical or chemical impact from being transmitted to electronic component 110, and can rapidly transfer heat generated by electronic components 110 outward.

FIG. 2D shows a cross-sectional view of electronic device 100 at a later stage of manufacture. In the example shown in FIG. 2D, encapsulant 140 can be provided on electronic components 110 and 110′, substrate 120, and interface material 130. Encapsulant 140 can contact, cover, or encapsulate electronic components 110 and 110′, substrate 120, and interface material 130. Encapsulant 140 can comprise or be referred to as an epoxy mold compound, a resin, a sealant, a filler-reinforced polymer, a B-stage pressed film, a gel, or an organic body. In some examples, encapsulant 140 can comprise an epoxy or phenol resin, carbon black and a silica filler. In some examples, encapsulant 140 can be provided by compression molding, transfer molding, liquid encapsulant molding, vacuum lamination, paste printing, film assist molding, or any other suitable deposition technique. The compression molding can be performed by supplying flowable resin to a mold in advance, placing a substrate into the mold, and then curing the flowable resin. Transfer molding can be performed with flowable resin supplied from a gate (supply port) of a mold to the periphery of an electronic component and then cured. The thickness of encapsulant 140 can range from approximately 100 μm to approximately 2000 μm. In some examples, encapsulant 140 comprises a thickness sufficient to completely cover electronic components 110′ in the finished electronic device 100.

Encapsulant 140 can provide protection for electronic components 110 and 110′ from external elements and/or environmental exposure and can rapidly emit heat generated from electronic components 110 and 110′. In some examples, encapsulant 140 can be located in the gap between electronic components 110 and 110′ and substrate 120. For example, encapsulant 140 can replace interface material 130 and interface material 130 can be omitted (e.g., encapsulant 140 can be molded underfill).

FIG. 2E shows a cross-sectional view of electronic device 100 at a later stage of manufacture. In the example shown in FIG. 2E, an upper portion of encapsulant 140 can be removed to reduce its thickness. In some examples, a grinding or an etching process can be used to remove the portion of encapsulant 140. In some examples, the upper portion of encapsulant 140 can be removed until second sides 112 of electronic components 110 are exposed from the top side of encapsulant 140. In some examples, portions of encapsulant 140 remain interposed between laterals sides 115 of adjacent electronic components 110. In some examples, second sides 112 of electronic components 110 and the top side of encapsulant 140 can be coplanar. In the present example, electronic components 110′ remain covered by encapsulant 140 so that electronic components 110′ are not exposed from the top side of encapsulant 140. In other examples, the encapsulant removal process can be omitted and encapsulant 140 can be provided with second sides 112 of electronic components 110 exposed from the top side of encapsulant 140 as part of the molding process.

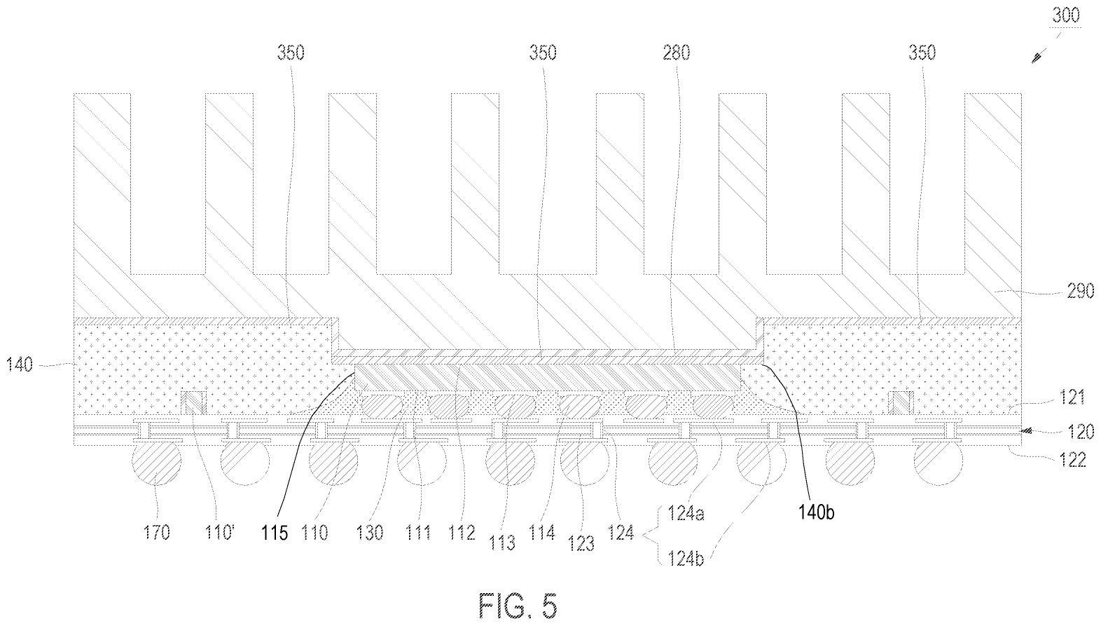

In some examples, a conductor or metallization layer (for example, metallization layer 350 shown in FIG. 5 and described in more detail later) can be provided on second sides 112 of electronic components 110 at this stage of manufacture. In some examples, the metallization layer can also be provided on the top side of encapsulant 140. In some examples, the metallization layer can be a continuous layer across the top side of encapsulant 140 and second sides 112 of electronic components 110. In some examples, the metallization layer can comprise Ti, Cu, Ni, or SnAg. In some examples, the metallization layer can also comprise Ni, Cu, In, Au, or Ag. In some examples, the metallization layer can be configured to enhance heat transfer away from electronic components 110, and as will be described later, can enhance the adhesion of other elements to electronic components 110, such TIM layers or heat sinks.

FIG. 2F shows a cross-sectional view of electronic device 100 at a later stage of manufacture. In the example shown in FIG. 2F, adhesive 150 can be provided on the top side of encapsulant 140 corresponding to an outer periphery of electronic device 100. In some examples, adhesive 150 can be provided on the top side of encapsulant 140 at a location overlying electronic components 110′. In some examples, adhesive 150 can be provided in the shape of a square or rectangular ring in a top view. In some examples, electronic components 110 are inside a perimeter or central portion defined by adhesive 150. In some examples, the width of adhesive 150 can be less than or equal to the width from the outer lateral side of encapsulant 140 to lateral side 115 of an outermost one of electronic components 110. In some examples, the width of adhesive 150 is less than the width of encapsulant 140 at the outer periphery of electronic device 100. In some examples, the width of adhesive 150 is greater than the width of encapsulant 140 at the outer periphery of electronic device 100 and adhesive can partially extend onto second side(s) 112 of the outer ones of electronic components 110.

Adhesive 150 can comprise or be referred to as an adhesive paste or adhesive film. In some examples, adhesive 150 can be applied in a liquid phase onto encapsulant 140 by a dispenser. In some examples, adhesive 150 can be applied as a film on encapsulant 140. In some examples, adhesive 150 can comprise a thermally curable adhesive, a photo-curable adhesive, or a non-curable adhesive (e.g., a rubber-based adhesive, an acryl-based adhesive, a vinyl alkyl ether-based adhesive, a silicone-based adhesive, a polyester-based adhesive, a polyamide-based adhesive, or a urethane-based adhesive). In some examples, adhesive 150 can be thermally conductive. The thickness of adhesive 150 can range from approximately 10 μm to 300 μm. In some examples, adhesive 150 comprises a thermally conductive material.

FIG. 2G shows a cross-sectional view of electronic device 100 at a later stage of manufacture. In the example shown in FIG. 2G, stiffener 160 can be provided on encapsulant 140 using adhesive 150. In some examples, stiffener 160 can be provided on the top side of adhesive 150 corresponding to the outer periphery of electronic device 100. In some examples, stiffener 160 can be provided on the top side of adhesive 150 overlying electronic components 110′. In some examples, stiffener 160 can be provided in the shape of a square or rectangular ring or flat lid type in the top view. In some examples, electronic components 110 are inside a perimeter defined by stiffener 160. In some examples, the width of stiffener 160 can be less than or equal to the width from the outer lateral side of encapsulant 140 to lateral side 115 of the outermost one of electronic components 110. In some examples, the width of stiffener 160 is less than the width of encapsulant 140 at the outer periphery of electronic device 100.

In some examples, stiffener 160 can overlap or contact second sides 112 of the outermost ones of electronic components 110. In some examples, stiffener 160 can comprise or be referred to as an extended stiffener, a brace, a support, a reinforcement, a rib, or a protuberance. In some examples, stiffener 160 can comprise a conductor or a dielectric. In some examples, stiffener 160 can be provided by placing/pressing, plating or depositing copper, a copper alloy, aluminum, an aluminum alloy, gold, a gold alloy, silver, a silver alloy, nickel, a nickel alloy, palladium, a palladium alloy, or tin silver on encapsulant 140 or adhesive 150. In some examples, stiffener 160 can be provided by placing/pressing/laminating, coating, or depositing a dielectric material or inorganic material, such as PI, BCB, PBO, resin, or ABF, on encapsulant 140 or adhesive 150. In some examples, stiffener 160 can comprise a copper base with a nickel-plated finish. In some examples, stiffener 160 can comprise stainless steel (e.g., SS304). The thickness of stiffener 160 can be in a range from approximately 100 μm to approximately 3500 μm.

In some examples, stiffener 160 can be implemented where electronic device 100 comprises a molded exposed die Flip Chip Ball Grid Array (FCBGA) configuration with smaller electronic components 110′ provided towards the periphery of substrate 120 and larger electronic components 110 towards the center of substrate 120. In some examples, this configuration helps to reduce package warpage. However, when thin core designs or coreless designs are used for substrate 120, it has become increasingly difficult to meet prescribed package warpage requirements. In accordance with the present description, electronic device 100 includes encapsulant 140 that covers electronic components 110′ and provides a laterally wider platform to support and facilitate a wider or extended stiffener 160. In this way, extended stiffener 160 is configured to reduce warpage of electronic device 100 including when substrate 120 comprises a thin core or is coreless. The wider or extended stiffener 160 of the present description provides enhanced support and stability to electronic device 100 and reduces warpage and defects associated with warpage, such as cracks or delamination.

FIG. 2H shows a cross-sectional view of electronic device 100 at a later stage of manufacture. In the example shown in FIG. 2H, external interconnects 170 can be provided on second side 122 of substrate 120.

External interconnects 170 can be coupled to conductive structure 124 exposed from substrate second side 122 of substrate 120. For example, external interconnects 170 can be coupled to substrate outward terminals 124b of conductive structure 124. In some examples, external interconnects 170 can comprise or be referred to as solder balls, solder coated metal (e.g., copper) core balls, pillars, pillars with solder caps, or bumps with solder caps. External interconnects 170 can comprise Sn, Ag, Pb, Cu, Sn—Pb, Sn37-Pb, Sn95-Pb, Sn—Pb—Ag, Sn—Cu, SnAg, Sn—Au, Sn—Bi, or SnAg—Cu. In some examples, external interconnects 170 can be provided through a reflow process after forming a conductive material including solder on second side 122 of substrate 120 in a ball drop method. External interconnects 170 can be used to couple electronic device 100 to an external device. In some examples, the thickness of each of external interconnects 170 can range from about 25 μm to about 1000 μm and external interconnects 170 can have a pitch of between about 25 μm to about 1000 μm. In other examples, external interconnects 170 are not used and electronic device 100 can comprise a Land Grid Array (LGA) configuration.

In some examples, multiple electronic devices 100 can be manufactured at the same time, for example, on a panel or carrier. The electronic devices 100 can be separated into individual electronic devices 100 by a singulation process. For example, individual electronic devices 100 can be provided by singulating (or cutting) through encapsulant 140, substrate 120, or stiffener 160. In some examples, the lateral sides of encapsulant 140, substrate 120, or stiffener 160 can be coplanar.

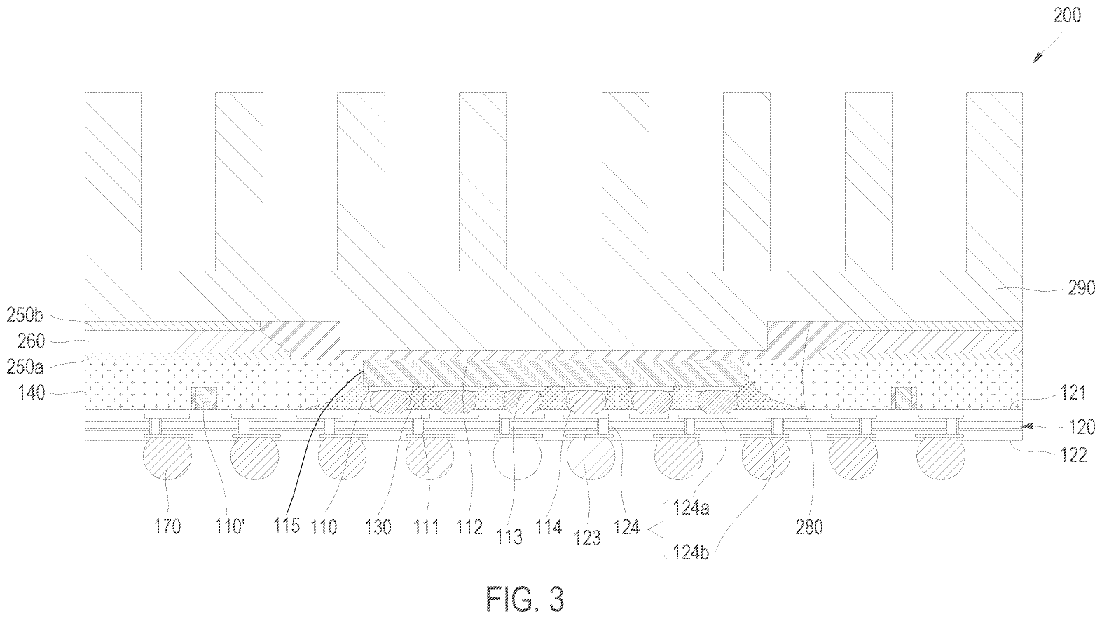

FIG. 3 shows a cross-sectional view of an example electronic device 200. Electronic device 200 has some similarities in construction to electronic device 100 and these similarities will not be repeated here. In this regard, only certain distinctions between the two electronic devices will be discussed hereinafter.

In the example of FIG. 3, electronic device 200 can comprise electronic component 110, contact pads 113, component interconnects 114, electronic components 110′, substrate 120, interface material 130, encapsulant 140, adhesives 250a and 250b, stiffener 260, thermal interface material (TIM) 280, heat sink 290, and external interconnects 170. In the present example, stiffener 260, TIM 280, and heat sink 290 are configured to reduce the effects of thermal stress on electronic device 200. Stiffener 260 and heat sink 290 are examples of a thermal stress reducing structure. Although electronic device 200 is shown with a single electronic component 110, it is understood that electronic device 200 can comprise multiple electronic components 110.

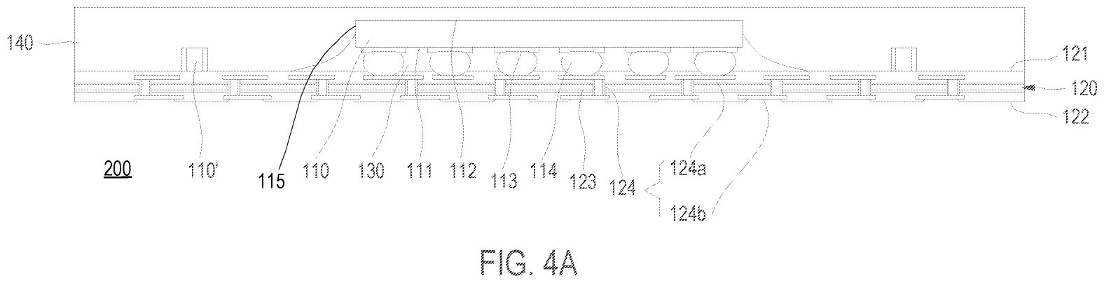

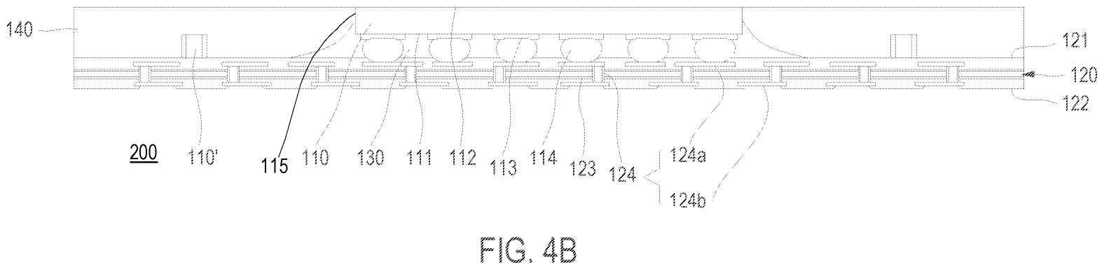

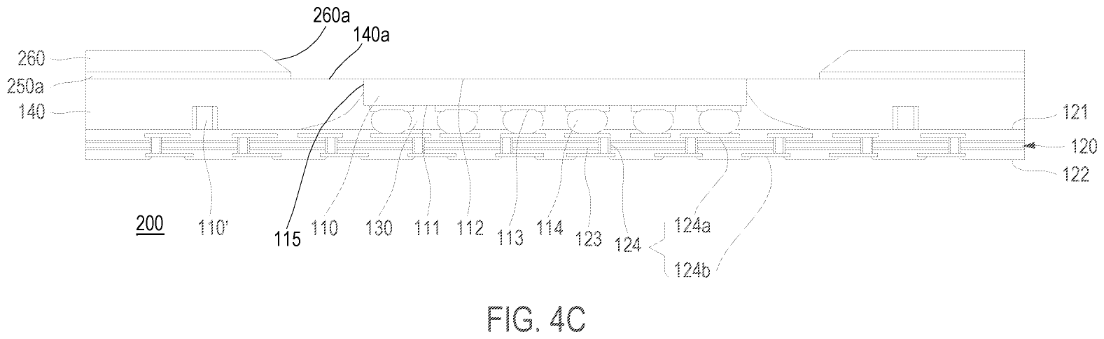

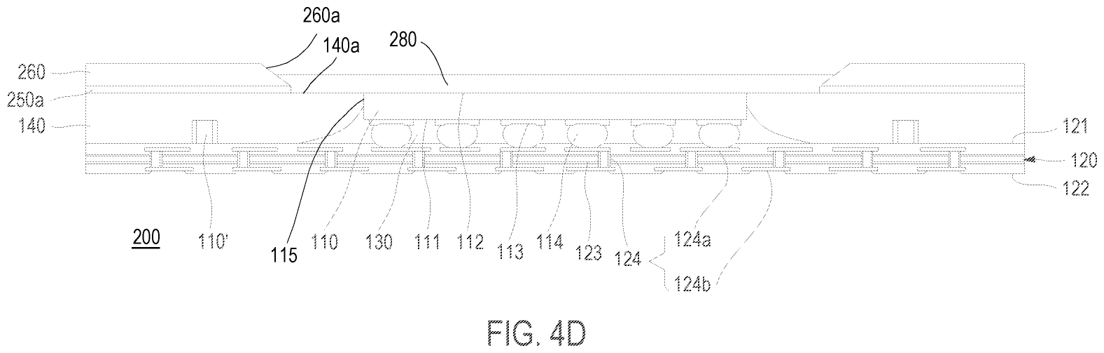

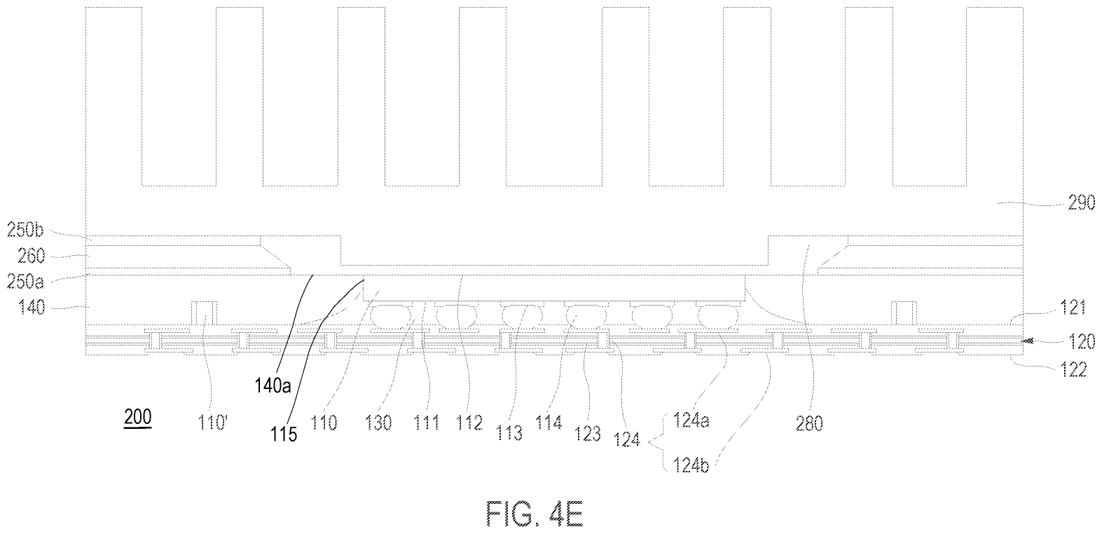

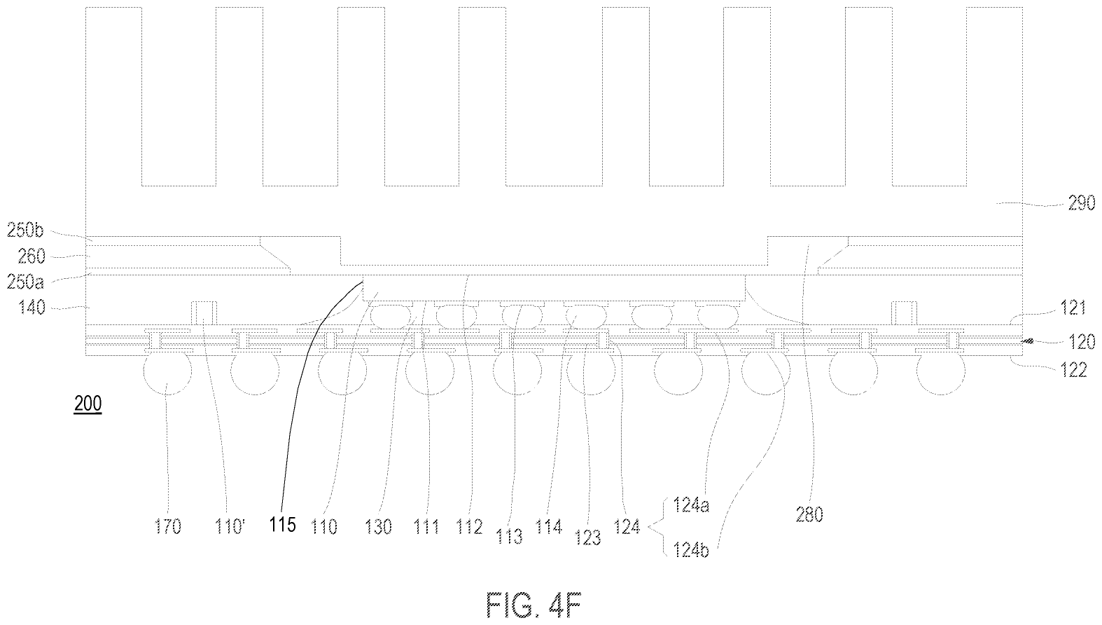

FIGS. 4A, 4B, 4C, 4D, 4E, and 4F show cross-sectional views of an example method for manufacturing an electronic device, such as electronic device 200. The method shown in FIGS. 4A to 4F has some similarities to the method shown in FIGS. 2A to 2H and these similarities will not be repeated here.

FIG. 4A shows a cross-sectional view of electronic device 200 at a later stage of manufacture. In the example shown in FIG. 4A, encapsulant 140 can be provided on electronic component 110, electronic components 110′, substrate 120, and interface material 130. Encapsulant 140 can contact, cover, or encapsulate electronic components 110 and 110′, substrate 120, and interface material 130. In some examples, interface material 130 contacts a portion of lateral side 115 of electronic component 110 and encapsulant 140 contacts a remaining portion of lateral side 115. In other examples, encapsulant 140 contacts lateral side 115 in its entirety. In some examples, interface material 130 can be omitted and encapsulant 140 can be disposed between electronic device 110 and first side 121 of substrate 120.

FIG. 4B shows a cross-sectional view of electronic device 200 at a later stage of manufacture. In the example shown in FIG. 4B, an upper portion of encapsulant 140 is removed. In some examples, a grinding process or an etching process can be used to remove the upper portion of encapsulant 140. In some examples, the upper portion of encapsulant 140 can be removed to expose second side 112 from a top side of encapsulant 140. In the present example, electronic components 110′ remain covered by encapsulant 140 so that electronic components 110′ are not exposed from the top side of encapsulant 140. In some examples, second side 112 of electronic component 110 and the top side of encapsulant 140 can be coplanar.

FIG. 4C shows a cross-sectional view of electronic device 200 at a later stage of manufacture. In the example shown in FIG. 4C, adhesive 250a can be provided on encapsulant 140 and stiffener 260 can be provided on adhesive 250a. In some examples, adhesive 250a can be provided on the top side of encapsulant 140 corresponding to an outer periphery of electronic device 200. In some examples, adhesive 250a can be provided on the top side of encapsulant 140 at a location overlying electronic components 110′. In some examples, adhesive 250a can be provided in the shape of a square or rectangular ring in a top view. In some examples, electronic component 110 is inside a perimeter defined by adhesive 250a. In some examples, the width of adhesive 250a can be less than or equal to the width from the outer lateral side of encapsulant 140 to lateral side 115 of electronic component 110. In some examples, the width of adhesive 250a is less than the width of encapsulant 140 leaving a portion 140a of the top side of encapsulant 140 exposed or uncovered. In some examples, the width of adhesive 250a is greater than the width of encapsulant 140.

Adhesive 250a can comprise or be referred to as an adhesive paste or adhesive film. In some examples, adhesive 250a can be applied in a liquid phase onto encapsulant 140 by a dispenser. In some examples, adhesive 250a can be applied as a film on encapsulant 140. In some examples, adhesive 250a can comprise a thermally curable adhesive, a photo-curable adhesive, or a non-curable adhesive (e.g., a rubber-based adhesive, an acryl-based adhesive, a vinyl alkyl ether-based adhesive, a silicone-based adhesive, a polyester-based adhesive, a polyamide-based adhesive, or a urethane-based adhesive). In some examples, adhesive 250a can be thermally conductive. The thickness of adhesive 250a can range from approximately 10 μm to 300 μm. Adhesive 250a is configured to couple stiffener 260 to encapsulant 140 in a later process.

In some examples, stiffener 260 can be provided on the top side of adhesive 250a corresponding to the periphery of electronic device 200. In some examples, stiffener 260 can be provided on the top side of adhesive 250a to overlap electronic component 110′. In some examples, stiffener 260 can be provided in the shape of a generally square or rectangular ring or flat lid type in the top view. In some examples, the width of stiffener 260 can be less than or equal to the width from the lateral side of encapsulant 140 to the outermost lateral side 115 of electronic component 110. In some examples, stiffener 260 can overlap or contact second side 112 of electronic component 110. In other examples, stiffener 260 is laterally spaced apart from second side 112 of electronic component 110 leaving portion 140a of the top side of encapsulant 140 exposed or uncovered.

In some examples, stiffener 260 can comprise or be referred to as an extended stiffener, a brace, a support, a reinforcement, a rib, or a protuberance. In some examples, stiffener 260 can comprise a conductor or a dielectric. In some examples, stiffener 260 can be provided by placing/pressing, plating or depositing copper, a copper alloy, aluminum, an aluminum alloy, gold, a gold alloy, silver, a silver alloy, nickel, a nickel alloy, palladium, a palladium alloy, or tin silver on encapsulant 140 or adhesive 250a. In some examples, stiffener 260 can be provided by placing/pressing/laminating, coating, or depositing a dielectric material or inorganic material, such as PI, BCB, PBO, resin, or ABF, on encapsulant 140 or adhesive 250a. The thickness of stiffener 260 can be in a range from approximately 10 μm to approximately 1000 μm. In some examples, stiffener 260 comprises a sloped or beveled inside edge 260a such that stiffener 260 has a first width proximate to adhesive 250a and a second width distal to adhesive 250a that is less than the first width.

FIG. 4D shows a cross-sectional view of electronic device 200 at a later stage of manufacture. In the example shown in FIG. 4D, TIM 280 can be provided on or overlapping second side 112 of electronic component 110. In some examples, TIM 280 can be provided on portion 140a of the top side of encapsulant 140 around electronic component 110. In some examples, TIM 280 can contact the lateral side of adhesive 250a or the lateral side (for example, beveled inner edge 260a) of stiffener 260.

In some examples, TIM 280 can comprise a liquid metal. In some examples, TIM 280 is other than a solid material. In some examples, TIM 280 comprises a thermally conductive material, such as gallium, gallium alloys, indium, tin, zinc, silver alloys, tin-silver, indium, or indium alloys. In some examples, TIM 280 is applied to both second side 112 of electronic component 110 and portion 140a of top side of encapsulant 140 using dispensing or printing processes. In other examples, TIM 280 can comprise a film attached to second side 112 of electronic component and portion 140a of encapsulant 140. The thickness of TIM 280 can be in a range from about 10 μm to about 300 μm. TIM 280 is configured to enhance or improve heat transfer between electronic component 110 and heat sink 290 thereby improving the reliability of electronic device 200.

FIG. 4E shows a cross-sectional view of electronic device 200 at a later stage of manufacture. In the example shown in FIG. 4E, heat sink 290 can be coupled to the top side of TIM 280. In some examples, heat sink 290 can also be coupled to stiffener 260. In some examples, heat sink 290 can be attached to electronic component 110 or encapsulant 140 using TIM 280 and attached to stiffener 260 using an adhesive 250b. Adhesive 250b can comprise similar materials as described for adhesive 250a and can be applied onto stiffener 260 before attaching heat sink 290 to adhesive 250b and TIM 280. In other examples, adhesive 250b can first be applied to heat sink 290 before attaching heat sink to stiffener 260 and TIM 280. In other examples, TIM 280 can be provided after heat sink 290 is attached to stiffener 260 through a passage provided in heat sink 290.

Heat sink 290 can comprise or be referred to as a lid, cover, or heat spreader and may or may not include fins. Heat sink 290 can comprise aluminum, an aluminum alloy, copper, a copper alloy, nickel, a nickel alloy, or other thermally conductive materials. The thickness of heat sink 290 can be variable and can range from approximately 100 μm to 5000 μm. Heat sink 290 is configured to further enhance heat transfer away from electronic component 110 thereby improving the reliability of electronic device 200. In some examples, the volume of TIM 280 is pre-selected so that TIM 280 remains substantially contained inside of a recess defined by adhesive 250a, stiffener 260, and adhesive 250b. In some examples, TIM 280 does not overlap onto the top side of adhesive 250b or onto the top side of stiffener 260 if adhesive 250b is not used. In some examples, heat sink 290 comprises a non-linear contact surface where heat sink 290 is coupled to TIM 280. In some examples, heat sink 290 comprises one or more outward extending protrusions. In some examples, the size of the protrusion(s) is selected to fit within the recess defined by adhesive 240a, stiffener 260, and adhesive 250b and to facilitate retaining the pre-selected volume of TIM 280 within the recess. In some examples, TIM 280 has a thickness that varies over its lateral width. In some examples, the thickness of TIM 280 over portions 140a of encapsulant 140 is thicker than the thickness of TIM 280 over second side 112 of electronic component 110.

FIG. 4F shows a cross-sectional view of electronic device 200 at a later stage of manufacture. In the example shown in FIG. 4F, external interconnects 170 can be provided on substrate 120. External interconnects 170 can be coupled to conductive structure 124 exposed from substrate second side 122 of substrate 120. For example, external interconnects 170 can be coupled to substrate outward terminals 124b of conductive structure 124. In other examples, external interconnects 170 are not used and electronic device 200 can comprise an LGA configuration. In some examples, multiple electronic devices 200 can be manufactured at the same time, for example, on a panel or carrier. The electronic devices 200 can be separated into individual electronic devices 100 by a singulation process, as previously described.

FIG. 5 shows a cross-sectional view of an example electronic device 300. Electronic device 300 has some similarities in construction to electronic device 200 and these similarities will not be repeated here. In this regard, only certain distinctions between the two devices will be discussed hereinafter. In the present example, heat sink 290 is an example of a thermal stress reducing structure.

In the example shown in FIG. 5, electronic device 300 can comprise electronic component 110, contact pads 113, component interconnects 114, electronic components 110′, substrate 120, interface material 130, encapsulant 140, TIM 280, heat sink 290, external interconnects 170, and metallization layer 350. In the present example, TIM 280, heat sink 290, and metallization layer 350 are configured to reduce the effects of thermal stress on electronic device 300. Although electronic device 300 is shown with a single electronic component 110, it is understood that electronic device 300 can comprise multiple electronic components 110.

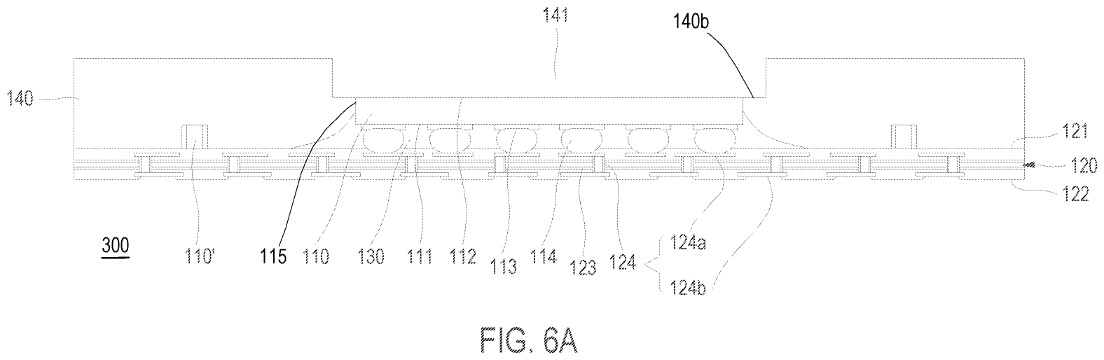

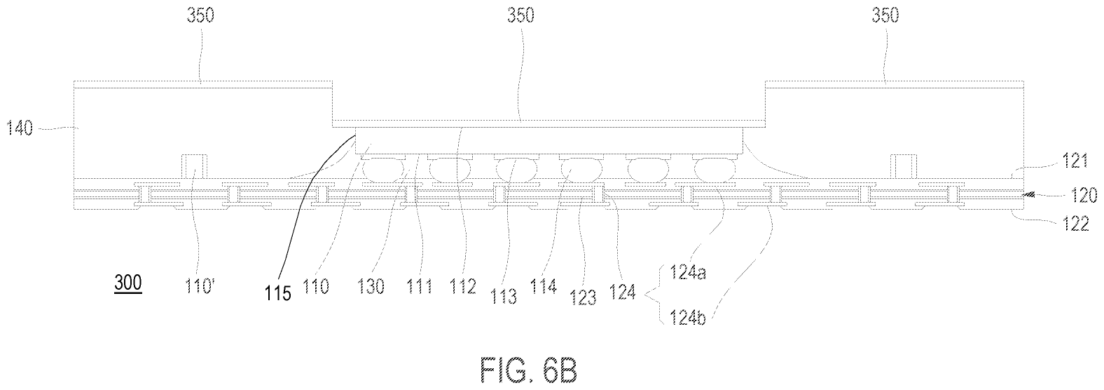

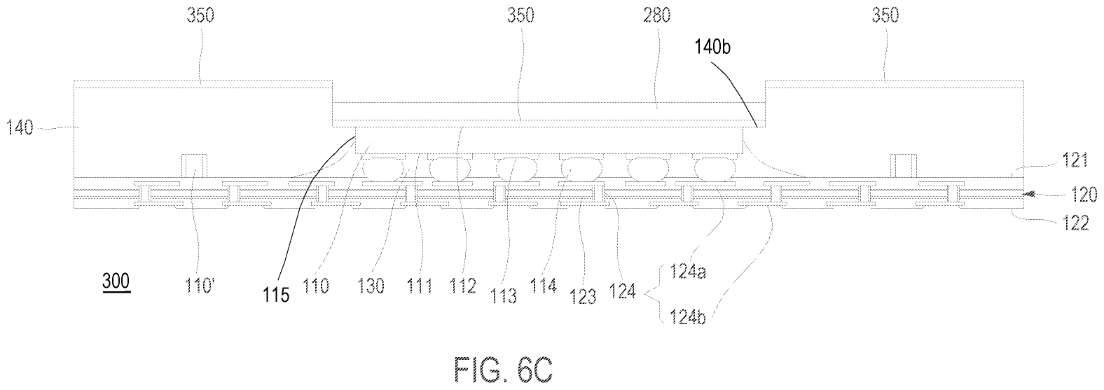

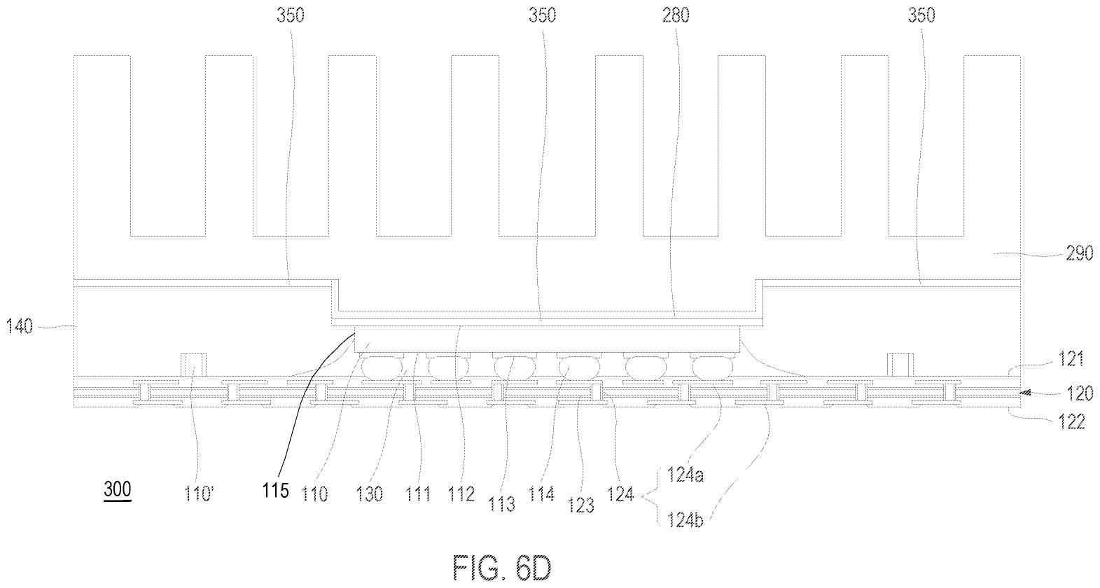

FIGS. 6A, 6B, 6C, and 6D show cross-sectional views of an example method for manufacturing an electronic device, such as electronic device 300. The method shown in FIGS. 6A to 6D has some similarities to the method shown in FIGS. 4A to 4F and these similarities will not be repeated here.

FIG. 6A shows a cross-sectional view of electronic device 300 at a later stage of manufacture. In the example shown in FIG. 6A, electronic component 110 can be encapsulated with encapsulant 140, but second side 112 of electronic component 110 can be exposed from a portion of the top side of encapsulant 140. In some examples, after electronic component 110 is molded with encapsulant 140, a portion of the top side of electronic component 110 and a corresponding portion of encapsulant 140 can be removed using, for example, grinding or etching processes. In some examples, a film assist molding process can be applied so that second side 112 of electronic component 110 is exposed. Through this process, recess 141 can be provided in encapsulant 140. Recess 141 can comprise a bottom side where second side 112 of electronic component 110 is exposed from encapsulant 140, and sidewalls along the outer perimeter of the bottom side. In some examples, the area (footprint) of recess 141 is greater than the area (footprint) of electronic component 110. In some examples, encapsulant 140 comprises a step 140b between the top side of encapsulant 140 and second side 112 of electronic component 110. Step 140b can also be referred to or comprise a shelf or inset portion. In some examples, the sidewalls of recess 141 can be beveled or sloped sidewalls.

FIG. 6B shows a cross-sectional view of electronic device 300 at a later stage of manufacture. In the example shown in FIG. 6B, a metallization layer 350 can be provided on second side 112 of electronic component 110 and the top side of encapsulant 140. In some examples, metallization layer 350 can also be referred to as or comprise a conductor or a conductive structure that comprises a high thermal conductivity and that adheres well to electronic component 110 and encapsulant 140 (e.g., Ti, Cu, Ni, In, Au, Ag, SnAg, etc.). In some examples, metallization layer 350 can be provided on the sidewalls of recess 141 so that metallization layer 350 is a continuous structure across the top side of encapsulant 140 and across electronic component 110.

In some examples, metallization layer 350 comprises a plurality of separate layers or sub-layers sequentially provided overlying each other. In some examples, metallization layer 350 can be formed by sequentially providing a Ti layer (for example, about 0.1 μm to about 0.2 μm thick), a Cu layer (for example, about 0.1 μm to about 0.2 μm thick), a Ni layer (for example, about 0.2 μm to about 0.3 μm thick), and an Au layer (for example, about 0.05 μm to about 0.2 μm thick) on the second side 112 of electronic component 110 and on the top side of encapsulant 140. In other examples, metallization layer 350 can be formed by sequentially providing a Ti layer (for example, about 0.1 μm to about 0.2 μm thick), a Cu layer (for example, about 0.1 μm to about 0.2 μm thick), a Ni layer (for example, about 0.2 μm to about 0.3 μm thick), and an SnAg layer (for example, about 10 μm to about 40 μm thick) on second side 112 of electronic component 110 and on the top side of encapsulant 140. In some examples, metallization layer 350 can be formed by sequentially providing a Ti layer (for example, about 0.1 μm to about 0.2 μm thick), a Cu layer (for example, about 0.1 μm to about 0.2 μm thick), a Ni layer (for example, about 2 μm to about 3 μm thick), a Cu layer (for example, about 3 μm to about 4 μm thick), and an Au layer (for example, about 0.05 μm to about 0.2 μm thick) on the second side of electronic component 110 and on the top side of encapsulant 140.

In some examples, a Ti layer (or a W layer, a Ta layer, etc.) is deposited as a barrier metal or a seed metal on second side 112 of electronic component 110 or on the top side of encapsulant 140, then a Cu layer can be deposited on the Ti layer. In some examples, the Ti layer and the Cu layer can be provided by CVD, LPCVD, PECVD, PVD, evaporation, sputtering, or ALD. In some examples, a plating process can be used. In some examples, a Ni layer is plated on the Cu layer as a barrier metal or a seed metal, then a SnAg layer can be plated on the Ni layer. In some examples, the Cu layer can be coupled to a negative electrode, and a Ni rod can be coupled to a positive electrode, followed by exposing the assembly to an electrolyte and applying a direct current power, thereby electroplating the Ni layer on the Cu layer. In some examples, the Ni layer can be coupled to a negative electrode, and a SnAg rod can be coupled to a positive electrode, followed by exposing the assembly to an electrolyte (e.g., an electrolyte containing SnAg) and applying a direct current power, thereby electroplating the SnAg layer on the Ni layer. In this way, the Ti layer, the Cu layer, the Ni layer, and the SnAg layer can be sequentially provided on second side 112 of electronic component 110 and on encapsulant 140 to provide metallization layer 350.

FIG. 6C shows a cross-sectional view of electronic device 300 at a later stage of manufacture. In the example shown in FIG. 6C, TIM 280 can be provided over second side 112 of electronic component 110 and a portion of encapsulant 140 (for example, step 140b) around electronic component 110. In some examples, TIM 280 can be provided on metallization layer 350 within recess 141 of encapsulant 140. In some examples, TIM 280 can be provided on the bottom side and sides walls of recess 141. In some examples, TIM 280 comprises a liquid TIM and the volume of TIM 280 is less than the volume of recess 141.

When TIM 280 is provided on metallization layer 350, the bonding strength between electronic component 110 and TIM 280 can be improved, which also promotes better heat transfer from electronic component 110 to heat sink 290. In addition, the material selected for metallization layer 350 can be configured to reduce the formation of any unwanted intermetallic compounds between metallization layer 350, TIM 280, or heat sink 290. Accordingly, even if electronic device 300 is placed in a high-temperature environment (for example, greater than about 150 degrees Celsius), any propagation of voids within TIM 280 can be minimized, and thus the thermal stability of electronic device 300 can be improved.

FIG. 6D shows a cross-sectional view of electronic device 300 at a later stage of manufacture. In the example shown in FIG. 6D, heat sink 290 can be provided on the top side of TIM 280. In some examples, heat sink 290 can also be provided on metallization layer 350 on the top side of encapsulant 140 around recess 141. In some examples, heat sink 290 can contact metallization layer 350 through TIM 280 or can contact metallization layer 350 in the absence of TIM 280. In some examples, heat sink 290 can be attached to metallization layer 350 that is over encapsulant 140 using a thermally conductive adhesive. The thermally conductive adhesive can be used to attach heat sink 290 to metallization layer over second side 112 of electronic component 110 when TIM 280 is not used. In some examples, TIM 280 is over the side walls of recess 141 after heat sink 290 is attached. In some examples, TIM 280 directly contacts the side walls of recess 141. In some examples, TIM 280 is contained inside of recess 141 so that metallization layer 350 over the top side of encapsulant 140 is devoid of TIM 280.

In accordance with the present description, metallization layer 350, TIM 280, and heat sink 290 are configured to improve the thermal dissipation capability of electronic device 300 thereby improving the reliability of electronic device 300. In addition, it was found empirically that when TIM 280 comprises a liquid TIM, defects associated with delamination and cracking caused by thermal stress are reduced further improving the reliability of electronic device 300.

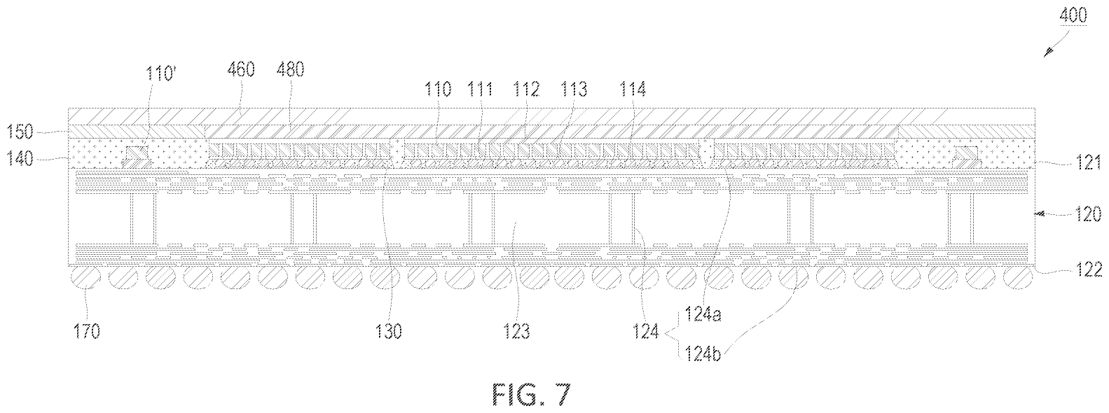

FIG. 7 shows a cross-sectional view of an example electronic device 400. Electronic device 400 shown in FIG. 7 has some similarities in construction to electronic device 100 shown in FIG. 1 and these similarities will not be repeated here. In this regard, only certain distinctions between the two electronic devices will be discussed hereinafter. Although electronic device 400 is shown with multiple electronic components 110, it is understood that electronic device 400 can comprise a single electronic component 110.

In the present example, electronic device 400 comprises a stiffener 460 that extends to overlap second sides 112 of electronic components 110. In some examples, stiffener 460 can cover the entire top side of electronic device 400. Stiffener 460 is an example of a thermal stress reducing structure. In some examples, peripheral portions of stiffener 460 can be attached to the top side of encapsulant 140 using adhesive 150, and a central portion of stiffener 460 can be attached to second sides 112 electronic components 110 using a TIM 480.

In some examples, stiffener 460 can comprise or be referred to as an extended stiffener, a lid, a brace, a support, a reinforcement, a rib, or a protuberance. In some examples, stiffener 460 can comprise a thermally conductive material. In some examples, stiffener 460 can be provided by placing/pressing, plating or depositing copper, a copper alloy, aluminum, an aluminum alloy, gold, a gold alloy, silver, a silver alloy, nickel, a nickel alloy, palladium, a palladium alloy, or tin silver, on encapsulant 140 or adhesive 150. In some examples, stiffener 460 can be provided by placing/pressing/laminating, coating, or depositing a dielectric material or inorganic material, such as PI, BCB, PBO, resin, or ABF, on encapsulant 140 or adhesive 150. The thickness of stiffener 460 can be in a range from approximately 10 μm to approximately 1000 μm.

In some examples, TIM 480 can comprise similar materials and can be provided using similar processing techniques as those described previously for TIM 280. In some examples, TIM 480 can comprise a liquid TIM. Accordingly, stiffener 460 can not only prevent warpage of electronic device 400 but also improve heat dissipation of electronic device 400 together with TIM 480. In some examples, the top side of adhesive 150 and the top side of TIM 480 can be substantially coplanar. Accordingly, the bottom side of stiffener 460 can also be substantially planar across electronic device 400. In other examples, metallization layer 350 can be provided across second sides 112 of electronic components 110, and TIM 480 can be on metallization layer 350.

In summary, structures and associated methods that relate to packaged electronic devices that are more resilient to thermal stress have been disclosed herein. More particularly, structures and methods have been described that improve the reliability of packaged electronic devices that reduce defects associated with thermal stress, such warpage, package distortion, bending, component cracking, or delamination. In some examples, a thermal stress reducing structure can comprise an extended stiffener overlying an encapsulant, which can be used to reduce warpage of thin packaging substrates, such as thin core or coreless substrates. In some examples, the thermal stress reducing structure can comprise a heat sink coupled to the extended stiffener. In some examples, a liquid thermal interface material (TIM) can be used together with the extended stiffener or the heat sink. In some examples, electronic components can be exposed from a top side of the encapsulant and can include a metallization layer that improves heat transfer performance and improves adhesion with the liquid TIM. In some examples, the encapsulant can cover electronic components at the periphery of the package substrate to provide extended support for the extended stiffener.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure is not limited to the examples disclosed, but that the disclosure will include all examples falling within the scope of the appended claims.

What is claimed is:

1. An electronic device, comprising:
a substrate comprising:
a first side comprising a peripheral portion and a central portion surrounded by the peripheral portion;
a second side opposite to the first side;
a dielectric structure; and
a conductive structure;
a first electronic component comprising:
a component first side coupled to the conductive structure at the first side of the substrate in the central portion;
a component second side opposite to the component first side; and
a component lateral side connecting the component first side to the component second side;
a second electronic component coupled to the first side of the substrate in the peripheral portion;
an encapsulant covering the second electronic component and the peripheral portion of the first side of the substrate, wherein the second side of the first electronic component is exposed from a top side of the encapsulant; and
a stiffener coupled to the top side of the encapsulant in the peripheral portion and overlapping the second electronic component.

2. The electronic device of claim 1, further comprising:
an adhesive coupling the stiffener to the top side of the encapsulant with.

3. The electronic device of claim 1, further comprising:
a metallization layer over the second side of the first electronic component and the top side of the encapsulant.

4. The electronic device of claim 1, further comprising:
a heat sink; and
a thermal interface material (a TIM) interposed between the second side of the first electronic component and the heat sink.

5. The electronic device of claim 4, wherein:
the TIM comprises a liquid TIM.

6. The electronic device of claim 4, wherein:
the stiffener comprises a ring shape that defines a central recess over the first electronic component; and
the TIM is within the central recess.

7. The electronic device of claim 1, further comprising:
a heat sink coupled to the stiffener and the second side of the first electronic component; and
a metallization layer interposed between the second side of the first electronic component and the heat sink.

8. The electronic device of claim 7, wherein:
the metallization layer is over the top side of the encapsulant in the peripheral portion.

9. The electronic device of claim 7, further comprising:
a thermal interface material (a TIM) interposed between the metallization layer and the heat sink;
wherein:
the TIM comprises a liquid TIM.

10. The electronic device of claim 1, wherein:
the substrate comprises a coreless substrate.

11. An electronic device, comprising:
a substrate comprising:
a first side comprising a peripheral portion and a central portion surrounded by the peripheral portion;
a second side opposite to the first side;
a dielectric structure; and
a conductive structure;
a first electronic component comprising:
a component first side coupled to the conductive structure at the first side of the substrate in the central portion;
a component second side opposite to the component first side; and
a component lateral side connecting the component first side to the component second side;
a second electronic component coupled to the first side of the substrate in the peripheral portion;
an encapsulant covering the second electronic component and the peripheral portion of the first side, wherein the second side of the first electronic component is exposed from a top side of the encapsulant; and
a thermal stress reducing structure comprising one or more of:
a stiffener coupled to the top side of the encapsulant in the peripheral portion and overlapping the second electronic component; or
a heat sink coupled to the second side of the first electronic component.

12. The electronic device of claim 11, wherein:
the thermal stress reducing structure comprises the stiffener;
the stiffener overlaps the second electronic component;
the first electronic component is among a plurality of first electronic components coupled to the first side of the substrate in the central portion;
each of the plurality of first electronic components comprises a second side exposed from the top side the encapsulant;
each of the plurality of first electronic components is laterally spaced apart; and
the encapsulant is interposed between adjacent ones of plurality of electronic components.

13. The electronic device of claim 11, further comprising:
a thermal interface material (a TIM);
wherein:
the thermal stress reducing structure comprises the heat sink;
the encapsulant comprises a recess extending inward from the top side of the encapsulant over the first electronic component;
the second side of the first electronic component is exposed from the top side of the encapsulant within the recess;
the TIM is within the recess; and
the heat sink is coupled to the second side of the first electronic component with the TIM.

14. The electronic device of claim 13, further comprising:
a metallization layer over the second side of the first electronic component a portion of the encapsulant within the recess;
wherein:
the substrate comprises a coreless substrate;
the metallization layer is interposed between the TIM and the second side of the first electronic component; and
the TIM comprises a liquid TIM.

15. The electronic device of claim 11, further comprising:
a thermal interface material (a TIM);
wherein:
the thermal stress reducing structure comprises the stiffener and the heat sink;
the stiffener comprises a ring shape that defines a central recess over the first electronic component;
a portion of the top side of the encapsulant is exposed within the central recess; and
the TIM is within the central recess and overlaps the portion of the top side of the encapsulant exposed within the central recess.

16. The electronic device of claim 11, further comprising:
a thermal interface material (a TIM); and
an adhesive;
wherein:
the thermal stress reducing structure comprises the stiffener;
the adhesive overlies the top side of the encapsulant but not the second side of the first electronic component;
the adhesive couples the stiffener to the top side of the encapsulant;
the stiffener extends to overlap the second side of the first electronic component; and
the TIM is interposed between the second side of the first electronic component and the stiffener.

17. A method of manufacturing an electronic device, comprising:
providing a substrate comprising:
a first side comprising a peripheral portion and a central portion surrounded by the peripheral portion;
a second side opposite to the first side;
a dielectric structure; and
a conductive structure;
providing a first electronic component comprising:
a component first side coupled to the conductive structure at the first side of the substrate in the central portion;
a component second side opposite to the component first side; and
a component lateral side connecting the component first side to the component second side;
providing a second electronic component coupled to the first side of the substrate in the peripheral portion;
providing an encapsulant covering the second electronic component and the peripheral portion of the first side, wherein the second side of the first electronic component is exposed from a top side of the encapsulant; and
providing a thermal stress reducing structure comprising one or more of:
a stiffener coupled to the top side of the encapsulant in the peripheral portion and overlapping the second electronic component; or
a heat sink coupled to the second side of the first electronic component.

18. The method of claim 17, wherein:
providing the thermal stress reducing structure comprises providing the stiffener;
providing the first electronic component comprises providing a plurality of first electronic components coupled to the first side of the substrate in the central portion;
each of the plurality of first electronic components comprises a second side exposed from the top side the encapsulant;
each of the plurality of first electronic components is laterally spaced apart; and
providing the encapsulant comprises providing the encapsulant interposed between adjacent ones of plurality of electronic components.

19. The method of claim 17, further comprising:
providing a metallization layer; and
providing a thermal interface material (a TIM);
wherein:
providing the substrate comprises providing a coreless substrate;
providing the thermal stress reducing structure comprises providing the heat sink;
providing the encapsulant comprises:
providing a recess extending inward from the top side of the encapsulant over the first electronic component; and
exposing the second side of the first electronic component from the top side of the encapsulant within the recess;
providing the metallization layer comprises providing the metallization layer over the second side of the first electronic component and over a portion of the encapsulant within the recess;
providing the TIM comprises providing a liquid TIM within the recess over the metallization layer; and
providing the heat sink comprises coupling the heat sink to the second side of the first electronic component with the TIM.

20. The method of claim 17, further comprising:
providing a thermal interface material (a TIM);
wherein:
providing the thermal stress reducing structure comprises providing the stiffener and the heat sink;
providing the stiffener comprises providing the stiffener comprises a ring shape that defines a central recess over the first electronic component;
providing the stiffener comprises providing a portion of the top side of the encapsulant is exposed within the central recess; and
providing the TIM comprises providing the TIM within the central recess and overlapping the portion of the top side of the encapsulant exposed within the central recess.
